(19) United States
(12) Patent Application Publication
(10) Pub. No.: US 2025/0253244 A1
(43) Pub. Date: Aug. 7, 2025

(54) CONDUCTIVE WIRES, INTERCONNECT STRUCTURES INCLUDING THE SAME, AND INTEGRATED CIRCUIT DEVICES INCLUDING THE SAME

(71) Applicants: Samsung Electronics Co., Ltd., Suwon-si (KR); UNIVERSITY-INDUSTRY COOPERATION GROUP OF KYUNG HEE UNIVERSITY, Yongin-si (KR)

(72) Inventors: Chang Seok LEE, Suwon-si (KR); Sangwon KIM, Suwon-si (KR); Seunghyun LEE, Yongin-si (KR); JUN SEONG BAE, Yongin-si (KR); MIN WOO LEE, Yongin-si (KR); JUN SU CHOI, Yongin-si (KR)

(21) Appl. No.: 19/046,330

(22) Filed: Feb. 5, 2025

(30) Foreign Application Priority Data
Feb. 6, 2024 (KR) 10-2024-0018120

(51) Int. Cl. H01L 23/532; H01L 23/522; H01L 23/528

(52) U.S. Cl. CPC H01L 23/53276; H01L 23/5223; H01L 23/5226; H01L 23/5228; H01L 23/5283

(57) ABSTRACT

Embodiments provides a conductive wiring, an interconnect structure including the conductive wiring, and an integrated circuit device including the conductive wiring. The conductive wiring includes a metal matrix, and linear carbon nanostructures electrically connected to the metal matrix and randomly arranged in a direction different from a width direction of the conductive wiring.

### CROSS-REFERENCE TO RELATED APPLICATION

This application claims priority to Korean Patent Application No. 10-2024-0018120 filed on Feb. 6, 2024, and all the benefits accruing therefrom under 35 U.S.C. § 119, the content of which in its entirety is herein incorporated by reference.

### BACKGROUND

### (a) Field of the Invention

Conductive wirings, interconnect structures, and integrated circuit devices are disclosed.

### (b) Description of the Related Art

In order to provide a high-performance integrated circuit device, technologies to reduce dimensions of the unit devices in the integrated circuit device have been studied, and accordingly, it is required to reduce the line width of the wirings electrically connecting the unit devices.

### SUMMARY

However, if the line width of the wiring is reduced below a predetermined range, the resistance may rapidly increase due to material limitations, resulting in deterioration of electrical properties.

An embodiment provides a conductive wiring capable of reducing or preventing deterioration of electrical characteristics while having a reduced line width.

Another embodiment provides an interconnect structure including the conductive wiring.

Another embodiment provides an integrated circuit device including the conductive wiring or the interconnect structure.

According to an embodiment, a conductive wiring electrically connecting unit devices includes a metal matrix, and linear carbon nanostructures electrically connected to the metal matrix and randomly arranged in a direction different from a width direction of the conductive wiring.

The linear carbon nanostructures may include carbon nanotubes, carbon nanofibers, carbon nanoribbons, or a combination thereof.

The metal matrix may have a polycrystalline structure with a plurality of grain boundaries, and the linear carbon nanostructures may be arranged to cross the grain boundaries of the metal matrix.

The linear carbon nanostructures may be arranged substantially parallel to a length direction of the conductive wiring.

Two opposite ends of each of the linear carbon nanostructures may be surrounded by the metal matrix.

The linear carbon nanostructures may be embedded in the metal matrix.

The conductive wiring may further include an auxiliary layer surrounding at least a part of the linear carbon nanostructures, the auxiliary layer including a metal oxide.

The metal oxide may include molybdenum oxide, aluminum oxide, hafnium oxide, bismuth oxide, titanium oxide, tantalum oxide, ruthenium oxide, or a combination thereof.

A thickness of the auxiliary layer may be greater than 0 and less than or equal to about 2 nanometers (nm).

The conductive wiring may not comprise a growth support and a metal catalyst for the linear carbon nanostructures.

The metal matrix may include palladium (Pd), ruthenium (Ru), molybdenum (Mo), copper (Cu), tungsten (W), hafnium (Hf), titanium (Ti), tantalum (Ta), platinum (Pt), chromium (Cr), rhodium (Rh), iridium (Ir), osmium (Os), an alloy thereof, or a combination thereof.

The linear carbon structures may be included in an amount of about 9% to about 20% with respect to a total volume of the conductive wiring.

The line width of the conductive wiring may be about 1 nm to 10 nm.

According to an embodiment, an interconnect structure includes one or more dielectric layers, and the conductive wiring positioned on at least one of upper, lower, and side portions of the one or more dielectric layers.

The conductive wiring may include a first conductive wiring, a second conductive wiring positioned at a different height from the first conductive wiring, and a via electrically connecting the first conductive wiring and the second conductive wiring.

The interconnect structure may further include an anti-scattering layer positioned on a surface of the conductive wiring.

The anti-scattering layer may include graphene, metal-doped graphene, or a combination thereof.

According to an embodiment, an integrated circuit device includes the conductive wiring or the interconnect structure.

The integrated circuit device may further include a transistor, a capacitor, a diode, a resistor, or a combination thereof, electrically connected to the conductive wiring.

Deterioration of electrical characteristics may be reduced or prevented while reducing the line width of the conductive wiring.

### BRIEF DESCRIPTION OF THE DRAWINGS

FIG. 1 is a top plan view showing an example of conductive wiring according to an embodiment,

FIGS. 2A to 2D are cross-sectional views schematically illustrating examples of distribution of the metal matrix and the linear carbon nanostructure along a thickness direction of the conductive wiring of FIG. 1,

FIG. 3 is a plan view showing another example of a conductive wiring according to an embodiment,

FIGS. 4A to 4D are cross-sectional views schematically illustrating examples of distribution of a metal matrix and a linear carbon nanostructure along a thickness direction of the conductive wiring of FIG. 3,

FIG. 5 is a cross-sectional view illustrating an example of an interconnect structure according to an embodiment,

FIG. 6 is a cross-sectional view illustrating another example of an interconnect structure according to an embodiment,

FIG. 7 is a cross-sectional view illustrating another example of an interconnect structure according to an embodiment,

FIG. 8 is a conceptual diagram illustrating an example of an electronic device according to an embodiment, and

FIG. 9 is a graph showing a change in current density according to a voltage of conductive wirings according to Examples 1 and 2 and Comparative Example 1.

### DETAILED DESCRIPTION

Hereinafter, the embodiments will be described in detail so that those of ordinary skill in the art can easily implement them. However, the actually applied structure may be implemented in several different forms and is not limited to the embodiments described herein.

The terms used herein are merely for the purpose of describing example embodiments, and are not intended to limit the present disclosure. The singular expression includes the plural expression unless the context clearly dictates otherwise.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Throughout the specification, the terms “comprise” or “have” are intended to specify the presence of stated features, integers, steps, operations, constituent elements, components or a combination thereof, but do not preclude the presence or addition of one or more other features, integers, steps, operations, constituent elements, components, and/or groups thereof.

In the drawings, the thickness of layers and regions may be exaggerated for clarity, and like reference numerals designate like elements throughout the specification. It will be understood that when an element such as a layer, film, region, or substrate is referred to as being “on” or “above” another element, it can be “directly on” the other element or intervening elements may also be present. In contrast, when an element is referred to as being “directly on” another element, there are no intervening elements present. The drawings and description are to be regarded as illustrative in nature and not restrictive. Like reference numerals designate like elements throughout the specification. It will be understood that when a component is referred to as being “on” or “over” another component, the component can be directly on, under, on the left of, or on the right of the other component, or can be on, under, on the left of, or on the right of the other component in a non-contact manner.

In addition, unless explicitly described to the contrary, the word “comprise,” and variations such as “comprises” or “comprising,” will be understood to imply the inclusion of stated elements but not the exclusion of any other elements.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements.

The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below. Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The term “layer” includes a construction having a shape formed on a part of a region, in addition to a construction having a shape formed on an entire region.

As used herein, the term “the” or similar indicative terms correspond to both the singular form and the plural form. The steps of all methods described herein can be performed in any suitable order unless otherwise indicated herein or otherwise clearly contradicted by context.

Also, terms such as “unit.” “module,” etc., as used in the present specification may refer to a part for processing at least one function or action and may be implemented as hardware, software, or a combination of hardware and software.

The connecting lines, or connectors shown in the various figures presented are intended to represent example functional relationships and/or physical or logical couplings between the various elements.

It should be noted that many alternative or additional functional relationships, physical connections or logical connections may be present in a practical apparatus.

As used herein, “at least one of A, B, or C,” “one of A, B, C, or a combination thereof” and “one of A, B, C, and a combination thereof” refer to each constituent element, and a combination thereof (e.g., A; B; C; A and B; A and C; B and C; or A, B and C). Herein, “combination thereof” refers to a mixture, a stacked structure, a composite, an alloy, a blend, for example.

Hereinafter, unless otherwise defined, “substantially”, “approximately” or “about” includes not only the stated value, but also the average within an allowable range of deviation, considering the error associated with the measurement and amount of the measurement. For example, “substantially”, “approximately” or “about” may mean within ±10%, 5%, 3%, or ±1% of the indicated value or within a standard deviation. Hereinafter, “metal” is interpreted as a concept including metals and metalloids (semimetals).

Hereinafter, an example of a conductive wiring according to an embodiment will be described with reference to the drawings.

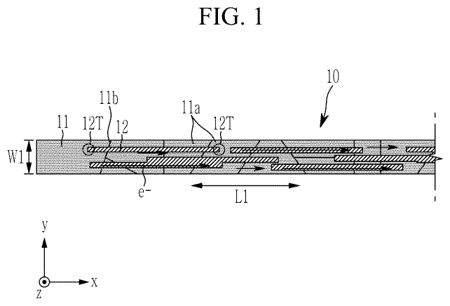

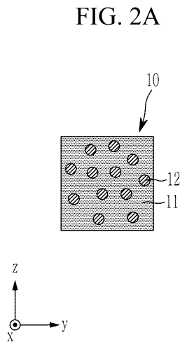

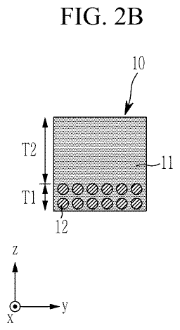

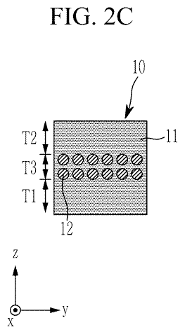

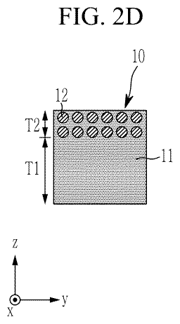

FIG. 1 is a top plan view showing an example of conductive wiring according to an embodiment, and FIGS. 2A to 2D are cross-sectional views schematically illustrating examples of distribution of the metal matrix and the linear carbon nanostructure along a thickness direction (z-direction) of the conductive wiring of FIG. 1.

The conductive wiring 10 may include any wiring that transmits an electrical signal or requires an electrical connection, and may include, for example, any wiring electrically connecting between active elements, passive elements, and/or between active elements and passive elements in a semiconductor device.

The conductive wiring 10 may be a three-dimensional structure having a width W1, a length, L1 and a thickness, herein a length direction (x-direction) of the conductive wiring 10 may be a direction in which electrons move and may be perpendicular to the width direction (y-direction) and the thickness direction (z-direction), respectively.

The line width W1 of the conductive wiring 10 may be in the range of a nanometer to several tens of nanometers, for example, about 30 nm or less, about 20 nm or less, about 10 nm or less, about 7 nm or less, about 5 nm or less, about 1 nm to 30 nm, about 1 nm to 20 nm, about 1 nm to 10 nm, about 1 nm to 7 nm, or about 1 nm to 5 nm.

Referring to FIG. 1, the conductive wiring 10 according to an embodiment includes a metal matrix 11 and a plurality of linear carbon nanostructures 12.

The metal matrix 11 may be a conductive base material forming of the conductive wiring 10, and may fill a space excluding the plurality of linear carbon nanostructures 12 in the conductive wiring 10. The metal matrix 11 may include, a low-resistance metal having a relatively low resistance, or an alloy thereof, for example, palladium (Pd), ruthenium (Ru), molybdenum (Mo), copper (Cu), tungsten (W), cobalt (Hf), hafnium (Hf), titanium (Ti), tantalum (Ta), platinum (Pt), chromium (Cr), rhodium (Rh), iridium (Ir), osmium (Os), alloys thereof, or a combination thereof, but is not limited thereto. Here, the metal alloy may include a metal oxide, a metal nitride, a metal oxynitride, or a combination thereof, having conductivity comparable to that of metals, for example, ruthenium oxide (RuOₓ), titanium nitride (TiN), tantalum nitride (TaN), or a combination thereof, in addition to an alloy including two or more kinds of metals.

The metal matrix 11 may have a polycrystalline structure with a plurality of grains 11a and a plurality of grain boundaries 11b, which are boundaries between the adjacent grains 11a, due to the characteristics of the bulk metal material. The grain boundaries 11b may be formed in a direction crossing the length direction (x-direction) (e.g., the movement direction of electrons) of the conductive wiring 10, and for example, may be formed in the width direction (y-direction) of the conductive wiring 10 and/or may be obliquely formed in the width direction (y-direction) of the conductive wiring 10.

The linear carbon nanostructures 12 may be a one-dimensional graphenic nanostructures formed by rolling a graphene crystal lattice made of one layer of carbon atoms, and may be a semiconducting material or a metallic material. The linear carbon nanostructures 12 may include, for example, carbon nanotubes CNTs, carbon nanofibers, carbon nanoribbons, or a combination thereof, for example, semiconducting single-walled CNTs, metallic single-walled CNTs, semiconducting multi-walled CNTs, metallic multi-walled CNTs, metallic multi-walled CNTs, and/or carbon nanofibers.

The linear carbon nanostructures 12 are electrically connected to the metal matrix 11 and may be arranged in a direction different from the width direction (y-direction) of the conductive wiring 10. Adjacent linear carbon nanostructures 12 may be arranged parallel to each other or may be arranged inclined at a predetermined angle, for example, the plurality of linear carbon nanostructures 12 may be formed in a form dispersed in a dispersion, and thus may be randomly arranged in a direction different from the width direction (y-direction) of the conductive wiring 10. Here, ‘randomly’ may mean contrary to a structure patterned at substantially equal intervals and aligned side by side, and the spacing between adjacent linear carbon nanostructures 12 may be different from each other, and the ends of the linear carbon nanostructures 12 may not be arranged in a line.

On the other hand, the linear carbon nanostructures 12 may be provided into the conductive wiring 10 in a grown form, and for example, a structure that grows directly in the conductive wiring 10 may be excluded. Accordingly, the conductive wiring 10 may not include a growth support and a metal catalyst required to grow the carbon nanostructures, and since the plurality of linear carbon nanostructures 12 are not grown simultaneously in the conductive wiring 10, a structure in which the plurality of linear carbon nanostructures 12 protrude side by side from the growth support may be excluded.

For example, the plurality of linear carbon nanostructures 12 may be intersected at the grain boundaries 11b of the metal matrix 11, thereby effectively reducing the interference of electron movement, such as electron scattering at the grain boundaries 11b of the metal matrix 11, and providing a ballistic transport channel of electrons.

Specifically, when the conductive wiring 10 is made up of only the metal matrix 11, which is a bulk metal material, as the line width W1 of the conductive wiring 10 is narrowed to a nanometer to tens of nanometers (e.g., less than about 30 nm, less than about 20 nm, or less than about 10 nm), the electron mean free path of the bulk metal material constituting the metal matrix 11 may be longer than the line width W1 of the conductive wiring 10 during electron movement, causing electron scattering at the grain boundary 11b of the metal matrix 11 to cause a rapid increase in the resistance of the conductive wiring 10. On the other hand, the plurality of linear carbon nanostructures 12 may provide a passage for electrons regardless of the arrangement of the grain boundaries 11b of the metal matrix 11 and control the direction of movement of electrons in one direction to effectively reduce or prevent electrons from being scattered at the grain boundary 11b and changing the moving direction or slowing the moving speed of electrons, and thus a rapid increase in resistance of the conductive wiring 10 may be effectively reduced or prevented.

For example, each linear carbon nanostructure 12 may be arranged substantially parallel to the length direction (x-direction) of the conductive wiring 10, which is the moving direction of electrons, and for example, may be arranged at an angle of ±30 degrees, ±25 degrees, 20 degrees, ±15 degrees, ±10 degrees, 5 degrees, ±3 degrees, ±2 degrees, or 0 degrees with respect to the length direction (x-direction) of the conductive wiring 10.

Each linear carbon nanostructure 12 may be surrounded by a metal matrix 11, for example, two opposite ends of each linear carbon nanostructure 12, i.e., tips 12T of each linear carbon nanostructure 12 may be surrounded by a metal matrix 11.

The plurality of linear carbon nanostructures 12 may be variously disposed along a thickness direction (z direction) of the conductive wiring 10.

For example, referring to FIG. 2A, the plurality of linear carbon nanostructures 12 may be embedded in the metal matrix 11. For example, the plurality of linear carbon nanostructures 12 may be uniformly or non-uniformly distributed along the thickness direction (z direction) of the conductive wiring 10, and the metal matrix 11 may be filled in a space other than the plurality of linear carbon nanostructures 12. For example, the plurality of linear carbon nanostructures 12 may be locally arranged at a predetermined position of the conductive wiring 10 in the thickness direction (z direction).

For example, referring to FIG. 2B, the conductive wiring 10 may include a lower region T1 in which the plurality of carbon nanostructures 12 are arranged and an upper region T2 formed of the metal matrix 11, along the thickness direction (z-direction) of the conductive wiring 10. In the lower region T1, the metal matrix 11 may be filled in a space other than the plurality of linear carbon nanostructures 12.

For example, referring to FIG. 2C, the conductive wiring 10 may include a lower region T1 and an upper region T2 formed of the metal matrix 11, and an intermediate region T3 in which the plurality of linear carbon nanostructures 12 are arranged, along the thickness direction (z direction) of the conductive wiring 10. In the intermediate region T3, the metal matrix 11 may be filled in a space other than the plurality of linear carbon nanostructures 12.

For example, referring to FIG. 2D, the conductive wiring 10 may include a lower region T1 formed of a metal matrix 11 and an upper region T2 in which a plurality of linear carbon nanostructures 12 are arranged, along the thickness direction (z-direction) of the conductive wiring 10. In the upper region T2, the metal matrix 11 may be filled in a space other than the plurality of linear carbon nanostructures 12.

The plurality of linear carbon nanostructures 12 may be included in an amount of about 5% to 30% based on the total volume of the conductive wiring 10, and within the range, about 7% to 25% or about 9% to 20%.

As described above, the conductive wiring 10 includes the metal matrix 11 and the plurality of linear carbon nanostructures 12, even if it has a narrow line width of a nanometer to tens of nanometers (e.g., less than about 30 nm, less than about 20 nm, or less than about 10 nm), the effect of electron scattering at the metal grain boundary due to the decrease in line width may be effectively reduced or prevented.

Hereinafter, another example of the conductive wiring according to an embodiment will be described with reference to the drawings.

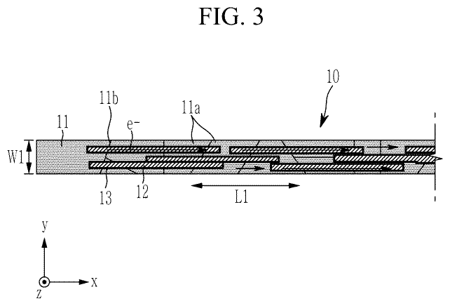

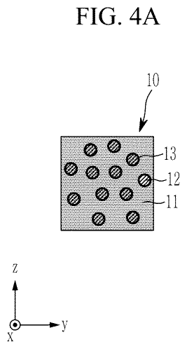

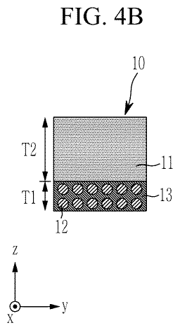

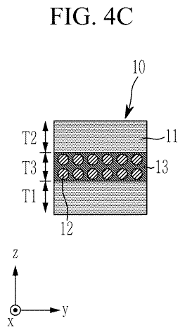

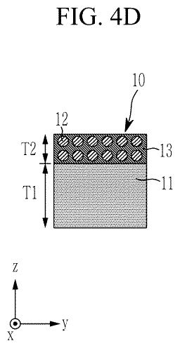

FIG. 3 is a plan view showing another example of a conductive wiring according to an embodiment, and FIGS. 4A to 4D are cross-sectional views schematically illustrating examples of distribution of a metal matrix and a linear carbon nanostructure along a thickness direction of the conductive wiring of FIG. 3.

Referring to FIG. 3, the conductive wiring 10 according to the present example includes the metal matrix 11 and the plurality of linear carbon nanostructures 12, as in the aforementioned example.

However, unlike the aforementioned example, the conductive wiring 10 according to this present example further includes the auxiliary layer 13 surrounding at least a part of the linear carbon nanostructures 12.

The auxiliary layer 13 may surround at least a part of the linear carbon nanostructures 12 with a very thin thickness, for example, it may surround each of the linear carbon nanostructure 12 or whole of the plurality of linear carbon nanostructures 12. The auxiliary layer 13 may be positioned between each linear carbon nanostructure 12 and the metal matrix 11 to prevent direct contact between each linear carbon nanostructure 12 and the metal matrix 11, thereby effectively lowering the contact resistance between each linear carbon nanostructure 12 and the metal matrix 11.

The auxiliary layer 13 is not particularly limited as long as it is a dielectric material that may be formed thinly, for example a thickness of about 2 nm or less, on the surface of each of the linear carbon nanostructure 12 or the plurality of linear carbon nanostructures 12, and may be, for example, a high-k dielectric material that may be formed by atomic layer deposition ALD. For example, the auxiliary layer 13 may include a metal oxide, for example, molybdenum oxide, aluminum oxide, hafnium oxide, bismuth oxide, titanium oxide, tantalum oxide, ruthenium oxide, or a combination thereof, but is not limited thereto.

The auxiliary layer 13 may have a thickness greater than 0 and less than or equal to about 2 nm, for example, a thickness of about 0.1 nm to 2 nm, about 0.3 nm to 2 nm, about 0.5 nm to 2 nm, or about 0.5 nm to 1.5 nm.

The auxiliary layer 13 may easily control electron injection from the metal matrix 11 to the linear carbon nanostructures 12 by effectively reducing the contact resistance between each linear carbon nanostructures 12 and the metal matrix 11, as described above, thereby further lowering the resistance of the conductive wiring 10 and further improving the conductivity the conductive wiring 10.

For example, referring to FIG. 4A, the plurality of linear carbon nanostructures 12 surrounded by the auxiliary layer 13 may be embedded in the metal matrix 11. The plurality of linear carbon nanostructures 12 surrounded by the auxiliary layer 13 may be uniformly or non-uniformly distributed along the thickness direction (z direction) of the conductive wiring 10, and the metal matrix 11 may be filled in a space other than the plurality of linear carbon nanostructures 12 surrounded by the auxiliary layer 13.

For example, referring to FIG. 4B, the conductive wiring 10 may include a lower region T1 in which the plurality of carbon nanostructures 12 surrounded by the auxiliary layer 13 are arranged and an upper region T2 formed of the metal matrix 11, along the thickness direction (z direction) of the conductive wiring 10.

For example, referring to FIG. 4C, the conductive wiring 10 may include a lower region T1 and an upper region T2 formed of a metal matrix 11, and an intermediate region T3 in which the plurality of linear carbon nanostructures 12 surrounded by the auxiliary layer 13 are arranged, along the thickness direction (z direction) of the conductive wiring 10.

For example, referring to FIG. 4D, the conductive wiring 10 may include a lower region T1 formed of the metal matrix 11 and an upper region T2 in which a plurality of linear carbon nanostructures 12 surrounded by the auxiliary layer 13 are arranged, along the thickness direction (z-direction) of the conductive wiring 10.

As described above, the conductive wiring 10 includes the metal matrix 11 and the plurality of linear carbon nanostructures 12 surrounded by the auxiliary layer 13, and thus effectively reducing the contact resistance between the linear carbon nanostructures 12 and the metal matrix 11, in addition to the effect of reducing the effect of electron scattering at the grain boundaries due to the decrease in line width in the metal grain system, thereby further lowering the resistance of the conductive wiring 10 and further improving the conductivity of the conductive wiring 10.

The above-described conductive wiring 10 may extend in a horizontal and/or vertical direction on a substrate (not shown), and may be embedded in a trench of a dielectric layer to form an interconnect structure electrically connecting one or more devices.

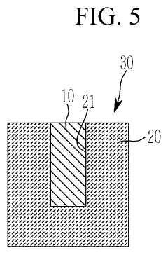

FIG. 5 is a cross-sectional view illustrating an example of an interconnect structure according to an embodiment.

Referring to FIG. 5, an interconnect structure 30 according to an embodiment includes a dielectric layer 20 and a conductive wiring 10.

A substrate (not shown) may be disposed under the dielectric layer 20, and the substrate may be a semiconductor substrate. The semiconductor substrate may include, for example, a group IV semiconductor material, a group Ill-V semiconductor compound, or a group II-VI semiconductor compound, and may include, for example, the group IV semiconductor material including at least one of Si, Ge, Sn, C, B, Ga, In, and Al, the Group III-V compound semiconductor material in which at least one of B, Ga, In, and Al and at least one of N, P, As, Sb, S, Se, and Te are combined, or a group II-VI compound semiconductor material in which at least one of Be, Mg, Cd, and Zn and at least one of O, S, Se, and Te are combined. For example, the semiconductor substrate may include Si, Ge, SiC, SiGeC, SiGeC, Ge alloy, GaAs, InAs, InP, and the like, but is not limited thereto.

At least one semiconductor device (not shown) may be included inside and/or above the substrate, and for example, at least one of a transistor, a capacitor, a diode, and a resistor may be included, but is not limited thereto.

The dielectric layer 20 may include, for example, a (semi) metal oxide, a carbon-doped (semi) metal oxide, a (semi) metal carbide, a hydrogenated (semi) metal carbide, a (semi) metal nitride, a (semi) metal oxynitride, or a combination thereof. The dielectric layer 20 may include, for example, AlO_{z} (0<z≤3/2, for example, Al₂O₃), AlN, ZrOₓ (0<x≤2), HfOₓ (0<x≤2), SiO₂, SiCO, SiCN, SiON, SiCOH, AlSiO, BN (boron nitride), or a combination thereof, but is not limited thereto. The dielectric layer 20 may include one or more trenches 21.

The conductive wiring 10 may be positioned on at least one of the upper, lower, and side portions of the dielectric layer 20, and for example, the conductive wiring 10 may be embedded in the trench 21 of the dielectric layer 20. The conductive wiring 10 includes the metal matrix 11 and the plurality of linear carbon nanostructures 12 as described above, and may optionally further include the auxiliary layer 13, and the detailed description is as described above.

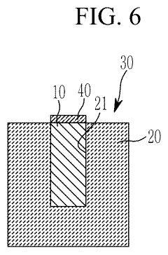

FIG. 6 is a cross-sectional view illustrating another example of an interconnect structure according to an embodiment.

Referring to FIG. 6, the interconnect structure 30 according to the present example includes the dielectric layer 20 and the conductive wiring 10, as in the above-described example. However, the interconnect structure 30 according to the present example may further include an anti-scattering layer 40 on the surface of the conductive wiring 10.

The anti-scattering layer 40 may effectively reduce electron scattering at the surface of the conductive wiring 10. As the line width W1 of the conductive wiring 10 is narrowed to a nanometer to tens of nanometers (e.g., about 30 nm or less, about 20 nm or less, or about 10 nm or less), the electron mean free path of the bulk metal material constituting the metal matrix 11 may be longer than the line width W1 of the conductive wiring 10, which may cause electron scattering at the surface of the conductive wiring 10 during electron movement, causing a rapid increase in resistance of the conductive wiring 10. The anti-scattering layer 40 may more effectively reduce or prevent a rapid increase in resistance of the conductive wiring 10 by reducing or preventing electron scattering at the surface of the conductive wiring 10.

The anti-scattering layer 40 may include graphene, metal-doped graphene, metal, or a combination thereof. The metal-doped graphene may include, for example, a p-type dopant, an n-type dopant, or a combination thereof, and the p-type dopant may be, for example, molybdenum oxide, but is not limited thereto. The metal may include, for example, cobalt (Co), but is not limited thereto.

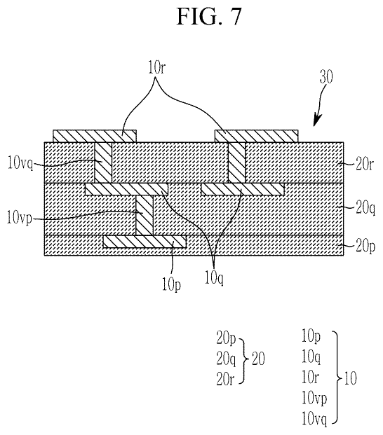

FIG. 7 is a cross-sectional view illustrating another example of an interconnect structure according to an embodiment.

Referring to FIG. 7, the interconnect structure 30 according to the present example includes the dielectric layer 20 and the conductive wiring 10, as in the above-described example.

However, the dielectric layer 20 may include a plurality of dielectric layers 20p, 20q, and 20r positioned at different heights from each other, and each of the dielectric layers 20p, 20q, and 20r may include the same or different materials. Each of the dielectric layers 20p, 20q, and 20r may have a trench 21, and the conductive wiring 10 may be embedded in each trench 21.

The conductive wiring 10 may include a plurality of conductive wirings 10p, 10q, and 10r and a plurality of vias 10vp and 10vq positioned at different heights from each other. That is, the conductive wiring 10 may include the first conductive wiring 10p, the second conductive wiring 10q positioned at a different height from the first conductive wiring 10p, the third conductive wiring 10r positioned at a different height from the first and second conductive wirings 10p and 10q, a via 10vp connecting the first conductive wiring 10p and the second conductive wiring 10q, and a via 10vq electrically connecting the second conductive wiring 10q and the third conductive wiring 10r. However, it is not limited to this, and the interconnect structure 30 may further include another conductive wire positioned at different heights or horizontally from the first, second, and/or third conductive wires 10p, 10q, 10r, and another via electrically connecting the adjacent conductive wires positioned at different heights from each other.

The first, second, and third conductive wirings 10p, 10q, and 10r and the vias 10vp and 10vq may be the same as the conductive wirings 10 described above, and may include the metal matrix 11 and the plurality of linear carbon nanostructures 12 as described above, and may optionally further include the auxiliary layer 13. The detailed description is as described above. The anti-scattering layer 40 may be formed on surfaces of the first, second, and third conductive wirings 10p, 10q, and 10r, and/or the vias 10vp and 10vq.

The conductive wiring 10 and/or the interconnect structure 30 described above may be included in an integrated circuit device. The integrated circuit device may be a DRAM or a logic device, but is not limited thereto. The integrated circuit device may include, for example, a unit device including a transistor, a capacitor, a diode, a resistor, or a combination thereof, electrically connected to the above-described conductive wiring 10. The integrated circuit device may be applied to, for example, a wiring (e.g., bit line, word line, etc.) connected to a unit device such as a transistor and/or a back end of line (“BEOL”) structure.

For example, the transistor may have various structures, such as fin field-effect transistor (“FinFET”), gate-all-around field-effect transistor (“GAAFET”), multi-bridge channel field-effect transistor (“MBCFET”), complementary field-effect transistor (“CFET”), or vertical field-effect transistor (“VFET”), but is not limited thereto. For example, the transistors may include a two-dimensional material as an active material and may be complementary field effect transistor (“C-FET”), multi-bridge channel field effect transistor (“MBC-FET”), or carbon nanotube field effect transistor (“CNT-FET”), but are not limited to them.

The conductive wiring 10, the interconnect structure 30 and/or the integrated circuit device described above may be included in various electronic devices. The electronic devices may include, for example, mobile devices, computers, laptops, tablet computer, smart watches, sensors, digital cameras, electronic books, network devices, car navigators, Internet of Things (“IoT”), Internet of Everything (“IoE”), drones, door locks, safes, automated teller machines (“ATM”), security devices, medical devices, automobile electrical components, etc. but are not limited thereto.

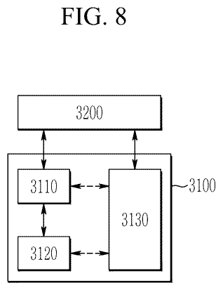

FIG. 8 is a conceptual diagram illustrating an example of an electronic device according to an embodiment.

Referring to FIG. 8, the electronic device 3100 according to an embodiment may include a memory unit 3110, an arithmetic logic unit 3120, and a control unit 3130, which may be electrically connected to one another. In an embodiment, for example, the memory unit 3110, the arithmetic logic unit 3120, and the control unit 3130 may be implemented as one chip, for example, monolithically integrated on one substrate. The memory unit 3110, the arithmetic logic unit 3120, and the control unit 3130 may independently include a transistor, a capacitor, a diode, a resistor, or a combination thereof. The electronic device 3100 may be connected to one or more input/output devices 3200.

Hereinafter, the embodiments are illustrated in more detail with reference to examples. However, these examples are exemplary, and the present scope is not limited thereto.

### Formation of Conductive Wiring

### Example 1

Single carbon nanotube powders (SIGMA-ALDRICH) and poly[9-(1-octylonoyl)-9H-carbazole-2,7-diyl], PCz) are dispersed in toluene and then performed a centrifugation and a vacuum filter filtration to prepare carbon nanotubes (CNTs). Then, the carbon nanotubes are dispersed in 1,1,2-trichloroethane to prepare a carbon nanotube dispersion with a concentration of about 5 μg/ml. Subsequently, a silicon wafer with a silicon oxide (SiO₂) film is immersed in the carbon nanotube dispersion through a dip coating, and 2-butene-1,4-diol is added near the silicon wafer. After that, the silicon wafer is taken out, cleaned by a solvent and dried to align the carbon nanotubes on the SiO₂ film. Subsequently, palladium (Pd) is deposited on the aligned carbon nanotubes at a thickness (line width) of 5 nm using a thermal evaporator under a 10⁻⁶ Torr vacuum condition at a 2 Å/sec deposition rate and then patterned it to prepare a conductive wiring with a CNT/Pd structure on the SiO₂ film.

### Example 2

Single carbon nanotube powders and poly[9-(1-octylonoyl)-9H-carbazole-2,7-diyl], PCz) are dispersed in toluene and then performed a centrifugation and a vacuum filter filtration to prepare carbon nanotubes (CNTs). Then, the carbon nanotubes are dispersed in 1,1,2-trichloroethane to prepare a carbon nanotube dispersion with a concentration of about 5 μg/ml. Subsequently, a silicon wafer with a silicon oxide (SiO₂) film is immersed in the carbon nanotube dispersion through a dip coating, and 2-butene-1,4-diol is added near the silicon wafer. After that, the silicon wafer is taken out, cleaned by a solvent and dried to align the carbon nanotubes on the SiO₂ film. Subsequently, aluminum oxide (AlOₓ, 0<x≤3) is deposited on the aligned carbon nanotubes by atomic layer deposition (ALD) to form an auxiliary layer with a thickness of 1 nm surrounding the carbon nanotubes. Subsequently, palladium (Pd) is deposited on the aligned carbon nanotubes at a thickness (line width) of 5 nm using a thermal evaporator under a 10⁻⁶ Torr vacuum condition at a 2 Å/sec deposition rate and then patterned it to prepare a conductive wiring with a CNT/AlOₓ/Pd structure on the SiO₂ film.

### Example 3

A conductive wiring with a CNT/MoOₓ/Pd structure is prepared on a silicon oxide (SiO₂) film according to the same way as in Example 2, except that the auxiliary layer is formed by using molybdenum oxide (MoOₓ, 0<x≤2) instead of aluminum oxide (AlOₓ, 0<x≤3).

### Example 4

A conductive wiring with a CNT/HfOₓ/Pd structure is prepared on a silicon oxide (SiO₂) film according to the same way as in Example 2, except that the auxiliary layer is formed by using hafnium oxide (HfOₓ, 0<x≤2) instead of aluminum oxide (AlOₓ, 0<x≤3).

### Example 5

Single carbon nanotube powders (SIGMA-ALDRICH) and poly[9-(1-octylonoyl)-9H-carbazole-2,7-diyl], PCz) are dispersed in toluene and then performed a centrifugation and a vacuum filter filtration to prepare carbon nanotubes (CNTs). Then, the carbon nanotubes are dispersed in 1,1,2-trichloroethane to prepare a carbon nanotube dispersion with a concentration of about 5 μg/ml.

Ruthenium (Ru) is deposited by atomic layer deposition (ALD) on a silicon wafer on which a silicon oxide (SiO₂) is formed, and then heated in an oven at about 340° C. for 2 hours to form a ruthenium oxide (RuOₓ) film with a thickness of 5 nm. Subsequently, the silicon wafer with the ruthenium oxide (RuOₓ) film is immersed in the carbon nanotube dispersion through a dip coating, and 2-butene-1,4-diol is added near the silicon wafer. After that, the silicon wafer is taken out, cleaned by a solvent and dried to align the carbon nanotubes on the SiO₂ film. Subsequently, palladium (Pd) is deposited on the aligned carbon nanotubes at a thickness (line width) of 5 nm using a thermal evaporator under a 10⁻⁶ Torr vacuum condition at a 2 Å/sec deposition rate and then patterned it to prepare a conductive wiring with a RuOₓ/CNT/Pd structure on the SiO₂ film.

### Example 6

Single carbon nanotube powders (SIGMA-ALDRICH) and poly[9-(1-octylonoyl)-9H-carbazole-2,7-diyl], PCz) are dispersed in toluene and then performed a centrifugation and a vacuum filter filtration to prepare carbon nanotubes (CNTs). Then, the carbon nanotubes are dispersed in 1,1,2-trichloroethane to prepare a carbon nanotube dispersion with a concentration of about 5 μg/ml.

Ruthenium (Ru) is deposited by atomic layer deposition (ALD) on a silicon wafer on which a silicon oxide (SiO₂) is formed, and then heated in an oven at about 340° C. for 2 hours to form a ruthenium oxide (RuOₓ) film with a thickness of 5 nm.

Subsequently, the silicon wafer with the ruthenium oxide (RuOₓ) film is immersed in the carbon nanotube dispersion through a dip coating, and 2-butene-1,4-diol is added near the silicon wafer. After that, the silicon wafer is taken out, cleaned by a solvent and dried to align the carbon nanotubes on the SiO₂ film.

Then, aluminum oxide (AlOₓ, 0<x≤3) is deposited on the aligned carbon nanotubes by an atomic layer deposition (ALD) method to form an auxiliary layer with a thickness of 1 nm surrounding the carbon nanotubes.

Subsequently, palladium (Pd) is deposited on the aligned carbon nanotubes at a thickness of 5 nm (line width) using a thermal evaporator under a 10⁻⁶ Torr vacuum condition at a 2 Å/sec deposition rate and then patterned it to prepare a conductive wiring with a RuOₓ/CNT/AlOₓ/Pd structure on the SiO₂ film.

### Example 7

A conductive wiring with a RuOₓ/CNT/MoOₓ/Pd structure is prepared on a silicon oxide (SiO₂) film according to the same way as in Example 6, except that an auxiliary layer is formed by using molybdenum oxide (MoOₓ, 0<x≤2) instead of aluminum oxide (AlOₓ, 0<x≤3).

### Example 8

A conductive wiring with a RuOₓ/CNT/HfOₓ/Pd structure is prepared on a silicon oxide (SiO₂) film according to the same way as in Example 6, except that an auxiliary layer is formed by using hafnium oxide (HfOₓ, 0<x≤2) instead of aluminum oxide (AlOₓ, 0<x≤3).

### Comparative Example 1

Palladium (Pd) is deposited on a silicon wafer on which a silicon oxide (SiO₂) is formed at a thickness (line width) of 6 nm using a thermal evaporator under a 10⁻⁶ Torr vacuum condition at a 2 Å/sec deposition rate and then patterned it to prepare a conductive wiring consisting of Pd on the SiO₂ film.

### Comparative Example 2

Ruthenium (Ru) is deposited by atomic layer deposition (ALD) on a silicon wafer on which a silicon oxide (SiO₂) is formed, and then heated in an oven at about 340° C. for 2 hours to form a ruthenium oxide (RuOₓ) film with a thickness of 5 nm. Subsequently, palladium (Pd) is deposited on the ruthenium oxide (RuOₓ) film at a thickness (line width) of 6 nm using a thermal evaporator under a 10⁻⁶ Torr vacuum condition at a 2 Å/sec deposition rate and then patterned it to prepare a conductive wiring with a RuOₓ/Pd structure on the SiO₂ film.

### Evaluation I

Sheet resistances of the conductive wires according to Examples and Comparative Examples are evaluated.

The sheet resistance is measured by the transmission line method (TLM).

The results are shown in Tables 1 and 2.

TABLE 1

| | Sheet Resistance (Ω/sq.) |
|---|---|
| Example 1 | 62.38 |
| Example 2 | 55.09 |
| Example 3 | 38.65 |
| Example 4 | 45.47 |
| Comparative Example 1 | 125.14 |

TABLE 2

| | Sheet Resistance (Ω/sq.) |
|---|---|
| Example 5 | 45.44 |
| Example 6 | 39.93 |
| Example 7 | 19.98 |
| Example 8 | 26.86 |
| Comparative Example 2 | 274.82 |

Referring to Tables 1 and 2, it may be confirmed that the conductive wirings according to Examples have lower sheet resistances as compared with the conductive wirings according to Comparative Examples.

From this, it may be expected that the conductive wirings according to Examples exhibit stable electrical characteristics without rapid increase in resistance, even if it has a narrow line width of about 10 nm or less.

### Evaluation II

Breakdown voltages of conductive wires according to Examples and Comparative Examples are evaluated.

The breakdown voltage of the conductive wiring is evaluated from the current density at the time when the resistance changes rapidly while changing the voltage applied to Au electrodes (gap between Au electrodes: 100 micrometers (μm), 200 μm, or 400 μm) on the conductive wirings according to Examples and Comparative Examples.

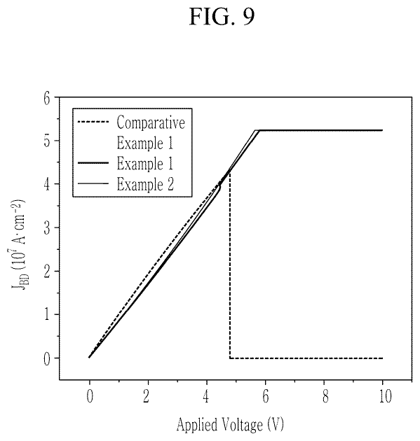

The result is shown in FIG. 9.

FIG. 9 is a graph showing a change in current density (unit: amperes per square centimeters: A/cm²) according to a voltage (unit: volt: V) of conductive wirings according to Examples 1 and 2 and Comparative Example 1.

Referring to FIG. 9, it may be confirmed that the conductive wirings according to Examples 1 and 2 do not show a breakdown voltage up to about 10V, whereas the conductive wiring according to Comparative Example 1 show a breakdown voltage around about 4.57V.

From this, it may be confirmed that the conductive wirings according to Examples 1 and 2 exhibit a higher breakdown voltage compared to the conductive wiring according to Comparative Example 1.

While the embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. A conductive wiring electrically connecting unit devices, the conductive wiring comprising:
a metal matrix, and
linear carbon nanostructures electrically connected to the metal matrix and randomly arranged in a direction different from a width direction of the conductive wiring.

2. The conductive wiring of claim 1, wherein the linear carbon nanostructures include carbon nanotubes, carbon nanofibers, carbon nanoribbons, or a combination thereof.

3. The conductive wiring of claim 1, wherein
the metal matrix has a polycrystalline structure with a plurality of grain boundaries, and
the linear carbon nanostructures are arranged to cross the grain boundaries of the metal matrix.

4. The conductive wiring of claim 1, wherein the linear carbon nanostructures are arranged substantially parallel to a length direction of the conductive wiring.

5. The conductive wiring of claim 1, wherein two opposite ends of each of the linear carbon nanostructures are surrounded by the metal matrix.

6. The conductive wiring of claim 1, wherein the linear carbon nanostructures are embedded in the metal matrix.

7. The conductive wiring of claim 1, further comprising an auxiliary layer surrounding at least a part of the linear carbon nanostructures, the auxiliary layer comprising a metal oxide.

8. The conductive wiring of claim 7, wherein the metal oxide comprises molybdenum oxide, aluminum oxide, hafnium oxide, bismuth oxide, titanium oxide, tantalum oxide, ruthenium oxide, or a combination thereof.

9. The conductive wiring of claim 7, wherein a thickness of the auxiliary layer is greater than 0 and less than or equal to about 2 nanometers (nm).

10. The conductive wiring of claim 1, wherein the conductive wiring does not comprise a growth support and a metal catalyst for the linear carbon nanostructures.

11. The conductive wiring of claim 1, wherein the metal matrix comprises palladium (Pd), ruthenium (Ru), molybdenum (Mo), copper (Cu), tungsten (W), hafnium (Hf), titanium (Ti), tantalum (Ta), platinum (Pt), chromium (Cr), rhodium (Rh), iridium (Ir), osmium (Os), an alloy thereof, or a combination thereof.

12. The conductive wiring of claim 1, wherein the linear carbon nanostructures are included in an amount of about 9% to about 20% with respect to a total volume of the conductive wiring.

13. The conductive wiring of claim 1, wherein a line width of the conductive wiring is about 1 nm to 10 nm.

14. An interconnect structure comprising:
one or more dielectric layers, and
the conductive wiring of claim 1 positioned on at least one of upper, lower, and side portions of the one or more dielectric layers.

15. The interconnect structures of claim 14, wherein the conductive wiring comprises:
a first conductive wiring,
a second conductive wiring positioned at a different height from the first conductive wiring, and
a via electrically connecting the first conductive wiring and the second conductive wiring.

16. The interconnect structures of claim 14, further comprising an anti-scattering layer positioned on a surface of the conductive wiring.

17. The interconnect structures of claim 16, wherein the anti-scattering layer comprises graphene, metal-doped graphene, or a combination thereof.

18. An integrated circuit device comprising the conductive wiring of claim 1.

19. An integrated circuit device comprising the interconnect structure of claim 14.

20. The interconnect structure of claim 19, further comprising a transistor, a capacitor, a diode, a resistor, or a combination thereof, which is electrically connected to the conductive wiring.
